(19) United States
(12) Patent Application Publication
(10) Pub. No.: US 2003/0079911 A1
(43) Pub. Date: May 1, 2003

(54) Discrete solder ball contact and circuit board assembly utilizing same

(76) Inventors: Robert M. Bogursky, Enoinitas, CA (US); Craig M. Kennedy, San Marcos, CA (US); Kenneth Krone, San Diego, CA (US); Joseph J. Lynch, San Marcos, CA (US)

Correspondence Address: ATTN: Michael H. Jester, THE LAW OFFICES OF MICHAEL H. JESTER, SYMPHONY TOWERS, SUITE 2560, 750 B STREET, SAN DIEGO, CA, 92101, US

(21) Appl. No.: 09/929,434

(22) Filed: Aug. 13, 2001

(51) Int. Cl. H05K 1/11

(52) U.S. Cl. 174/267

(57) ABSTRACT

Upper and lower planar circuit boards are connected in spaced apart parallel relationship by a plurality of contacts each made of a conductive pin, insulative collar and solder ball. The upper ends of the pins are inserted in plated though holes in the upper circuit board and soldered thereto by wave soldering or re-flow. The pins have shoulders to establish the penetration of the pins into the upper circuit board. The lower ends of the pins are bonded to conductive pads on the lower circuit board via the solder balls that are maintained in substantially round configuration by the insulative collars and accommodate variations in board co-planarity or pin length. Where the lower ends of the pins do not contact their corresponding conductive pads the volume of solder in the solder balls allows reliable fillet solder joints to be formed.

### CROSS-REFERENCE TO RELATED APPLICATIONS

This application is related to co-pending U.S. patent application Ser. No. 09/122,225 filed Jul. 24, 1998 of Craig Kennedy et al. entitled “Hybrid Solder Ball and Pin Grid Array Circuit Board Inter-Connecting System and Method” and U.S. patent application Ser. No. 09/520,427 filed Mar. 8, 2000 of Gregory K. Torigian et al. entitled “Conncetor with Base Having Channels to Facilitate Surface Mount Solder Attachment”, the entire disclosures of both of which are specifically incorporated herein by reference as though fully set forth.

### FIELD OF THE INVENTION

The present invention relates to electronic parts and assemblies that utilize surface mount technology (SMT), and more particularly, to the surface mounting of large components on printed circuit boards.

### BACKGROUND OF THE INVENTION

Difficulties in surface mount soldering of devices to circuit boards are well known. Some of the key factors that determine the nature and extent of these difficulties are the flatness of the circuit board, the co-planarity of the leads on the device, and the amount of solder required.

When solder paste is applied to a circuit board there needs to be physical contact between the paste and the leads on the device to be soldered in order to permit a proper solder joint to be formed after solder re-flow caused by heating. However, this imposes tight tolerances on the flatness of the circuit board and the co-planarity of the leads on the device. Presently the leads must be within approximately four thousandths of co-planarity. The thickness of the solder paste needs to be controlled extremely accurately, usually in the range of between six and eight thousandths of an inch. Since the “flatness” of conventional circuit boards can vary as much as ten thousandths of an inch per inch, surface mount connections are usually only made over short distances.

Solder balls have been used to allow SMT devices to be manufactured with wider tolerance ranges as to co-planarity of their leads and to permit the use of circuit boards with wider tolerances with regard to flatness. When pre-applied to either a device or a circuit board, solder balls provide more solder per joint than can typically be supplied with solder paste. So-called ball grid array (BGA) devices have been developed that utilize rows and columns of discrete solder balls to make the required electromechanical interconnections upon solder re-flow. The result is that SMT has been successfully employed with solder balls over areas as large as one and one-half inches square. A conventional BGA device 2 (FIGS. 1A and 1B) has solder balls 4 arranged in a grid pattern of rows and columns. Another conventional device 6 (FIGS. 2A, 2B and 2C) has a grid of balled pins 8. Typically conventional devices that utilize solder balls for attachment only have solder balls or balled pins located on one side and they have no other attachments because it is difficult to add balls or balled pins to a device that already has other components. When balls are added to pins by solder re-flow there must be some method of limiting the flow of solder or else the solder ball will substantially change its shape and thereby lessen its ability to accommodate tolerance variations. Therefore, at present, the type of devices that can be manufactured with balled pins is greatly limited.

There is a substantial need in the electronics industry to surface mount large products that contain other components. In the case of power supplies, for example, it is desirable to surface mount two parallel boards that overlap over a substantial area, e.g. two by four inches. It would be desirable to mount such large products to circuit boards with pins and solder balls but heretofore this has not been practical.

### SUMMARY OF THE INVENTION

In accordance with the present invention a surface mount contact is provided for attachment to a circuit board. The contact includes an elongate electrically conductive pin defining a shaft having a longitudinal axis and having an upper end and a lower end. A pre-formed heat re-flowable bonding member is attached to the lower end of the pin. An insulator surrounds the shaft of the pin intermediate the upper and lower ends and adjacent the pre-formed heat re-flowable bonding member.

The present invention also provides a circuit board assembly including an upper circuit board and a lower circuit board which are mechanically and electrically interconnected in spaced apart, parallel relationship by a plurality of electrically conductive pins. Each pin has a shaft with upper and lower ends. The upper ends of the pins are attached to the upper circuit board and the pins are arranged in a predetermined pattern. A plurality of separate discrete insulators each surround the shaft of a corresponding pin. The lower circuit board has a plurality of conductive pads arranged in the same predetermined pattern as the pins. A plurality of conductive joints are each formed by re-flow of pre-formed heat re-flowable bonding members previously attached to the lower ends of corresponding pins. Each conductive joint bonds a lower end of a corresponding pin and a corresponding conductive pad and forms an electromechanical connection therebetween.

A preferred embodiment of our circuit board assembly includes upper and lower generally planar circuit boards held in a predetermined spaced apart relationship by a plurality of electrically conductive pins. Each pin has a shaft with upper and lower ends. The upper ends of the pins are attached to plated through holes in the upper circuit board by a plurality of first solder joints. The pins extend from the underside of the upper circuit board in a predetermined pattern. A plurality of discrete insulators each surround the shaft of a corresponding pin. The lower circuit board opposes and is generally parallel with the upper circuit board. The lower circuit board has a plurality of conductive pads arranged in the same predetermined pattern as the pins extending from the upper circuit board. A plurality of second solder joints are formed by re-flowing a pre-formed heat re-flowable bonding member attached to the lower end of each pin. Each of the second solder joints bonds a lower end of a corresponding pin and a corresponding conductive pad. A first portion of the pins have lower ends that directly contact their corresponding conductive pads and a second portion of the pins have their lower ends spaced slightly above their corresponding conductive pads.

An alternate embodiment of our surface mount contact includes an elongate electrically conductive pin defining a shaft having a longitudinal axis and having an upper end and a lower end. A pre-formed heat re-flowable bonding member is attached to the lower end of the pin. An insulator with a conductive pad formed on an upper surface thereof surrounds the shaft of the pin adjacent the pre-formed heat re-flowable bonding member.

### BRIEF DESCRIPTION OF THE DRAWINGS

FIGS. 1A and 1B are simplified side elevation and top plan views, respectively, of a conventional ball-only BGA device.

FIGS. 2A and 2B are simplified side elevation and top plan views, respectively of a conventional pin and ball BGA device.

FIG. 2C is an enlarged side elevation view of one of the ball equipped pins of the BGA device illustrated in FIGS. 2A and 2B.

FIG. 3 is an enlarged side elevation view of a discrete solder ball contact in accordance with a first embodiment of the present invention.

FIGS. 4A is a fragmentary vertical sectional view illustrating re-flow soldering of the upper end of the contact of FIG. 3 into a plated through hole in an upper circuit board.

FIGS. 4B is a fragmentary vertical sectional view similar to FIG. 4A illustrating wave soldering of the upper end of a contact with a longer pin into a plated through hole in the upper circuit board.

FIG. 4C is a fragmentary vertical sectional view illustrating surface mounting of the upper end of an alternate embodiment of our contact to the underside of an upper circuit board.

FIG. 5A is a fragmentary top plan view illustrating tape and reel packaging of the discrete solder ball contact of FIG. 3.

FIG. 5B is a sectional view of the tape and reel packaging taken along line 5B-5B of FIG. 5A.

FIG. 6 is an enlarged side elevation view illustrating a circuit board assembly fabricated with a plurality of the discrete solder ball contacts of the type illustrated in FIG. 3.

FIG. 7A is an enlarged fragmentary vertical sectional view of the circuit board assembly of FIG. 6 illustrating the preferred solder ball joint achieved by re-flowing the solder ball of the contact of FIG. 3 when the lower end of the pin and its corresponding conductive pad contact each other.

FIG. 7B is an enlarged fragmentary vertical sectional view of the circuit board assembly of FIG. 6 illustrating a less desirable but still functional solder fillet joint obtained by re-flowing the solder ball of the contact of FIG. 3 when the lower end of the pin is spaced slightly above its corresponding conductive pad.

FIG. 8A is an enlarged vertical sectional view of an alternate embodiment of the contact that uses an insulator with a plated conductive pad and is adapted for through-hole mounting to a circuit board.

FIG. 8B is an enlarged vertical sectional view of yet another alternate embodiment of the contact that uses an insulator with a plated conductive pad and is adapted for surface mounting to a circuit board

FIG. 9 is an enlarged vertical sectional view of a further alternate embodiment of the contact which is similar to that of FIG. 8A except that the former does not have a plated conductive pad.

FIG. 10 is an enlarged vertical sectional view of still another embodiment of the discrete solder ball contact of the present invention that has a channeled head for surface mounting.

FIGS. 11 and 12 illustrate cylindrical and square washer-like pre-formed heat re-flowable bonding members, respectively, that may be used in place of the solder ball of the connector of FIG. 3.

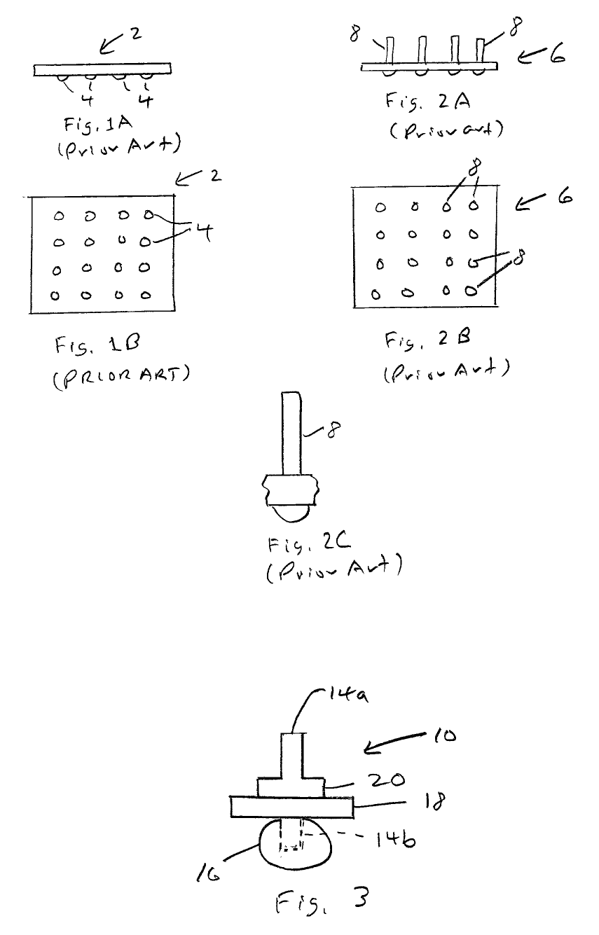

### DESCRIPTION OF TILE PREFERRED EMBODIMENTS

Referring to FIG. 3 a first embodiment of our surface mount contact 10 for attachment to a planar circuit board 12 (FIGS. 4A and 4B) includes an elongate electrically conductive pin 14 defining a cylindrical shaft having a longitudinal axis and having an upper end 14a and a lower end 14b. A solder ball 16 is bonded or otherwise attached to the lower end 14b of the pin 14. An insulator 18 in the form of a cylindrical collar surrounds the shaft of the pin 14 intermediate the upper and lower ends 14a and 14b and abuts the solder ball 16. The function of the insulator 18 is to prevent the solder ball 16 from significantly changing shape. The solder ball 16 preferably wraps around the lower end 14b of the pin 14 so that it covers both the flat circular end of the pin 14 and the lower portion of the cylindrical sidewall thereof The pin 14 is provided with a shoulder 20 above the insulator 16 for establishing a predetermined vertical position of the pin along the longitudinal axis relative to a reference surface which it abuts, which is the underside of the circuit board 12. The shoulder 20 need not be integrally formed with the pin 14 but could be a separate part mounted on the shaft of the pin 14.

FIG. 4A is a fragmentary vertical sectional view illustrating re-flow soldering of the upper end 14a of the pin 14 of the contact 10 into a plated through hole in the upper circuit board 12. The shoulder 20 abuts a conductive donut 21a on the underside of the upper circuit board 12 to control the depth of penetration of the shaft of the pin 14 so that it terminates below the upper side of the circuit board 12. The resulting solder joint 24 firmly mechanically attaches the contact 10 to the upper circuit board 12 and provides an electrical connection through the pin 14 to a conductive circuit trace (not illustrated) terminating in another conductive donut 21b on the upper side of the upper circuit board 12 that contacts the plated through hole.

FIG. 4B illustrates a slightly different version of the contact 10′ that has a longer pin 14′ that extends all the way through the plated through hole in the upper circuit board 12. Conventional wave soldering techniques are used to form a solder joint around the pin 14′ that includes a fillet 26 at the upper end of the joint.

FIG. 4C is fragmentary vertical sectional view illustrating surface mounting of the upper end of an alternate contact 30 to a conductive pad 31 conventionally formed on the underside of the upper circuit board 12. The contact 30 is described later on in connection with FIG. 10.

Contacts such as 10 can be used to fabricate a circuit board assembly 32 (FIG. 6) that includes the upper circuit board 12 and a planar lower circuit board 22 that opposes the upper circuit board 12 in spaced apart generally parallel relationship with the upper circuit board 12. The contacts 10 are attached to the upper circuit board 12 in a predetermined pattern, which may be rows and columns, or any other pattern. The upper ends 14a of the pins are inserted in plated through holes in the upper circuit board 12 and soldered thereto. At this time, the metal shoulders 20 also become bonded by the same solder to the underside of the plated through holes. The lower circuit board 22 has a plurality of conductive pads 34 formed on the upper side thereof in the conventional manner which are arranged in the same predetermined pattern as the contacts 10 and their pins 14 in order to be complementary with the upper circuit board 12. A plurality of solder joints such as 36 and 38 (FIGS. 7A and 7B) each formed by re-heating the solder ball 16 on each contact bridge any small distance between the lower end 14b of each corresponding pin 14 and its corresponding conductive pad 34. The solder joint 36 (FIG. 7A) is substantially rounded and results when the lower end of the pin 14′ contacts the conductive pad 34. The solder joint 38 (FIG. 7B) has the shape of a fillet and results when the lower end of the pin 14′ is spaced slightly above the conductive pad 34. The fillet shape of the solder joint 38 can also result from the insulator 18 being spaced too far above the solder ball 16. The solder ball 16 must have a sufficient quantity of solder such that when re-flowed, it will accommodate any pin and/or board non-co-planarity.

Thus the preferred embodiment of our circuit board assembly 32 includes upper and lower circuit boards 12 and 22 that are connected in closely spaced apart co-planar relationship by a plurality of contacts such as 10 or 10′ each including a pin such as 14. The upper ends 14a of the pins 14 are inserted in plated holes in the upper circuit board 12 and soldered thereto by wave soldering or re-flow. The pins 14 have shoulders 20 to establish the penetration of the pins 14 into the upper circuit board 12. The lower ends 14b of the pins 14 are bonded to conductive pads 34 on the lower circuit board 22 via solder balls 16 that form the solder joints 36 and 38 that together accommodate variations in pin and/or board co-planarity. The insulative collar 18 surrounding the shaft of each pin 14 intermediate its ends ensures that the exposed lower ends 14b of the pins 14 to be soldered completely around their circumference. The solder joint 38 extends around the outer cylindrical circumference of the lower end of the pin 14 and to its circular lower end to provide increased strength of attachment.

The insulator 18 (FIG. 3) is preferably press fit over the shaft of the pin 14. The insulator 18 is preferably made of a suitable plastic resin that can withstand high temperatures without degradation, such as a liquid crystal polymer. The insulator 18 is spaced above the lower end 14b of the pin 14 to permit the lower end 14b to be soldered around its entire circumference. The primary function of the insulator 18 is to provide a tight seal that prevents any of the solder from the re-flowed solder ball 16 from flowing past the insulator 18 along the shaft of the pin 14. The insulator 18 also prevents the solder ball 16 from dramatically changing its shape during attachment of the upper end 14a to the upper circuit board 12 and during subsequent re-heating to form a bond between the solder ball 16 and the conductive pad 34 on the lower circuit board 22. The pin 14 preferably has a round cross-section and is made of Copper or a Copper alloy to provide good electrical conductivity. The pin 14 maybe plated with Tin/Lead over Nickel or other suitable materials commonly used to fabricate electrical contacts that are to be soldered.

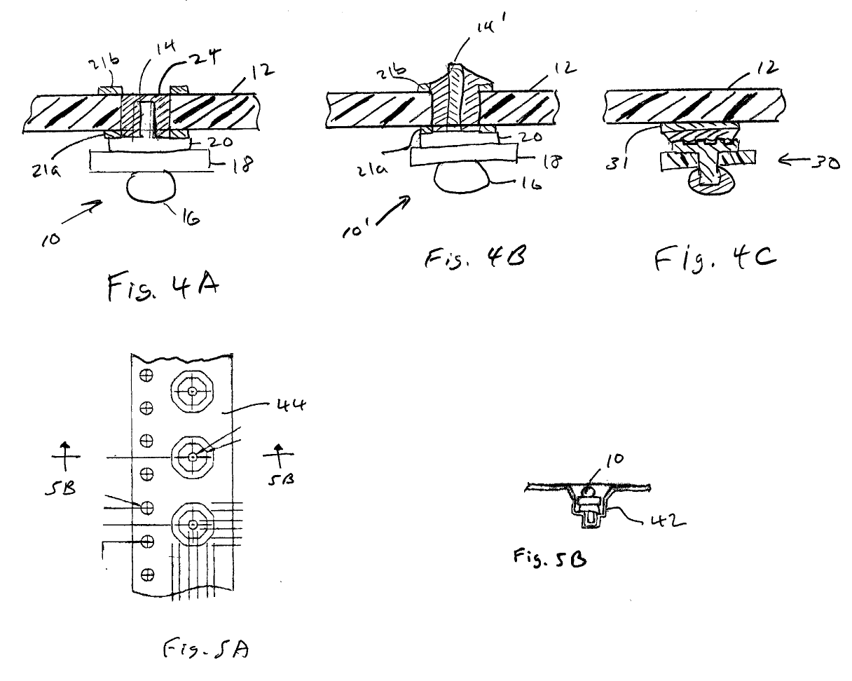

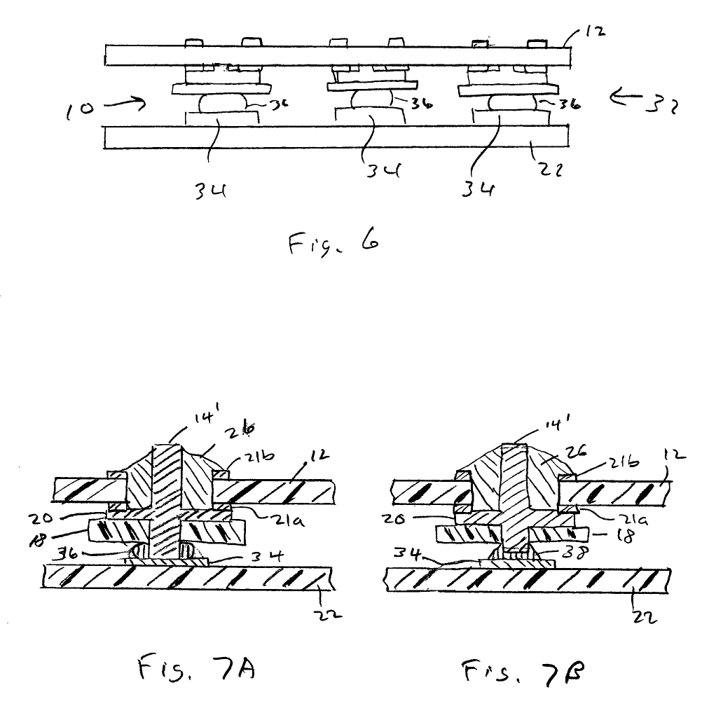

The contacts such as 10 can be packaged in receptacles 42 (FIG. 5B) in a conventionally formed tape 44 (FIG. 5A) wound on a reel and inserted in a feeder in an automatic pick and place machine. Placement on circuit boards can be accomplished utilizing a vacuum pick up nozzle. The pickup nozzle holds the solder ball 16 via suction and vision equipment sees the insulator 18 or the shoulder 20 (depending upon which is larger in diameter). This allows the automatic pick and place machine to place the pin 14 into a plated through hole in the circuit board 12. Where the upper end of a contact such as 30 (FIG. 4B) is surface mounted the pick and place machine would put the upper end on the corresponding conductive pad. Conventional pin-in-paste, wave soldering or paste-on-pad soldering techniques can be used. At present the preferred design is to make the diameter of the insulator 18 larger than that of the shoulder 20 but the arrangement could be visa versa. It is also possible for the diameter of the solder ball 16 to be the largest diameter on the contact 10 so that it would be recognized by the vision equipment.

High temperature solder is preferably used for bonding the upper ends of the contacts 10, 10′ or 30 to the upper circuit board 12 so that when the solder ball 16 is subsequently re-flowed to attach the contact to the lower circuit board 22, the attachment of the contact to the upper circuit board 12 would not be adversely affected, such as by re-flowing. Stated another way, the solder that bonds the upper ends of the contacts to the upper circuit board 12 preferably has a higher melting temperature than that of the solder balls 16. The melting point of the solder balls 16 depends upon the choice of the alloy for the solder which they are made from. When the solder balls 16 are re-flowed, they should preferably retain their substantially rounded shape illustrated in FIG. 7A.

When the contacts such as 10 are bonded to the conductive pads 34 on the lower circuit board 22 the upper circuit board 12 may be sufficiently heavy so that the lower ends 14b of some of the pins 14 actually rest on the conductive pads 34 as illustrated in FIG. 7A to provide a predetermined minimum spacing between the upper and lower circuit boards 12 and 22. Some of the lower ends 14b will not touch their corresponding conductive pads 34 as illustrated in FIG. 7B, due to non-co-planarity of the pins 14 and/or the lower circuit board 22. However, reliable solder joints 36 or 38 (FIGS. 7A and 7B) will still be formed due to the volume of solder in the balls 16 and the size of the conductive pads 34. These characteristics, as well as the size of the pins 14 and the amount of the pins 14 that are immersed in the solder balls 16 should be carefully selected to form the rounded solder joint 36 instead of the fillet joint 38 as much as possible.

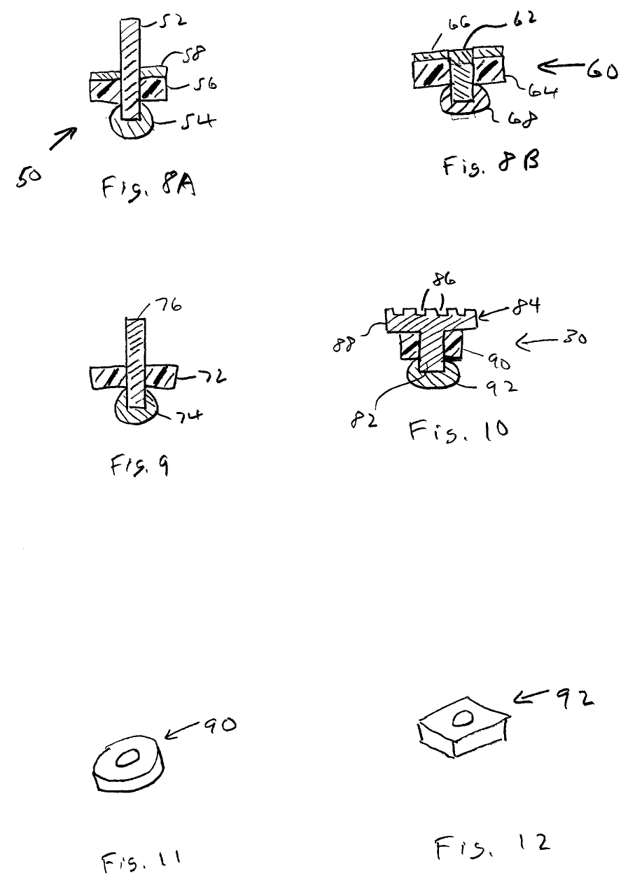

FIG. 8A illustrates an alternate embodiment of the contact 50 that is adapted for throug-hhole mounting to a circuit board. It includes a straight pin 52 that has a solder ball 54 attached to its lower end. A cylindrical insulator 56 is press fit over and surrounds the pin 52 and has a plated on conductive pad 58 on the upper side thereof The insulator 56 and conductive pad 58 can be formed as a miniature circuit board made of Copper clad FR-4 material. The insulator 56 serves to maintain the shape of the solder ball 54, while its conductive pad 58 allows the contact 50 to be soldered to a conductive pad such as 31 (FIG. 4C) formed on the lower side of an alternate form of the upper circuit board 12. The insulator 56 can be placed at various longitudinal positions along the straight pin 52 to permit different spacings between the upper and lower circuit boards 12 and 22 to be established. The contact 50 may not have as much current carrying capacity as the contact 10 (FIG. 3) since the former has less overall metal content however it may be easier and cheaper to fabricate.

FIG. 8B illustrates yet another alternate embodiment of the contact 60 that is adapted for surface mounting to a conductive pad 31 on the underside of the upper circuit board 12. It uses a shorter straight pin 62 than the contact 50. A cylindrical insulator 64 with a plated conductive pad 66 on an upper side thereof is press fit over the straight pin 62. The pin 62 does not extend through the insulator 64 so that the conductive pad 66 can be surface mounted and soldered to the conductive pad 31 on the underside of the upper circuit board 12. A solder ball 68 is attached to the lower end of the straight pin 62. The insulator 64 and conductive pad 66 can also be formed as a miniature circuit board made of Copper clad FR-4 material.

FIG. 9 illustrates yet another embodiment 70 that is similar to the embodiment 50 of FIG. 8A except that the later does not have any conductive pad on the upper side of its insulator 72. A solder ball 74 is attached to the lower end of a straight pin 76. The upper end of the straight pin 76 is soldered in place in the plated through hole in the upper circuit board 12 but the insulator 72 has no solder attachment to the upper circuit board 12. It merely functions as a spacer. The pin 76 could be stripped insulated rod or wire.

FIG. 10 illustrates yet another embodiment of our contact 30. It is similar to the contact 10 except that the shoulder 20 is eliminated and instead the upper end of the pin 82 is formed with a cylindrical head 84 for surface mounting to conductive pads such as 31 (FIG. 4C) formed on the underside of the upper circuit board 12. The head 84 is formed with a plurality of outwardly opening radially extending channels 86 in its upper surface. The upper surface of the channeled head 84 provides the principal contact with the conductive pad 31 on the underside of the circuit board 12. The channels preferably also open through the peripheral cylindrical outer wall 88 of the head 84 to permit out-gassing of vaporized solder flux. This minimizes skating during solder re-flow. Solder joint strength is also improved because the channels 86 increase the area of contact between the re-flowed solder and the head 84 of the pin 82. The channels 86 could be formed by a plurality of diametric channels that intersect in the middle of the head 84 or a crisscross pattern. The head 84 could have a wide variety of configurations as described and illustrated in U.S. patent application Ser. No. 09/520,427 incorporated by reference above. A cylindrical insulator 90 is press fit over the shaft of the pin 82 until it abuts the head 84. A solder ball 92 is attached to the lower end of the pin 82.

In the embodiments described so far, the contacts have utilized the solder ball 16 to make a connection to a lower circuit board 22. However it will be understood by those skilled in the art that the solder ball 16 could be replaced with a wide variety of pre-formed heat re-flowable bonding members that can be heated to cause them to re-flow, and thereafter when allowed to cool and re-solidify, will provide an electromechanical connection between the lower end of the pin 14 and the conductive pad 34. Heat for re-flow is preferably supplied via a conventional infrared source, although convection and other conventional heating techniques for solder re-flow may be used.

FIGS. 11 and 12 illustrate cylindrical and square pre-formed washer-like solder elements 90 and 92, respectively, that can be formed on, or press fit over, the lower end of the pin 14. They may surround the lower end 14b of the pin so that they are flush with its perpendicular lower circular surface. The elements 90 and 92 may also be spaced below the lower end 14b of the pin 14, or extend above the same. The elements 90 and 92 may abut the insulator 18 or be slightly spaced below the same.

When the customer solders the upper ends of the contact 10 in the plated through holes of the upper circuit board 12, the elements 90 and 92 will re-flow and form solder balls adjacent the insulator 18. These solder balls may cool and harden as the assembly moves down to the next automatic fabrication station where the upper circuit board 12 with its array of attached pins 14 can be inverted and placed on top of the second circuit board 22 before re-flowing the solder balls. The pre-formed heat re-flowable bonding members could also take the form of a discrete quantity of a suitable solder paste applied to the lower ends 14b of the pins in a manner to ensure that the paste will adhere thereto during the assembly and re-flow operations. Besides Tin/Lead alloys, the pre-formed heat re-flowable bonding member attached to the lower end 14b of each contact 10 may be made of Tin-Bismuth alloy, conductive epoxy, brazing compound, welding compound and the like. Thus one skilled in the art will appreciate that the circuit board assembly 32 could be fabricated with these various different types of pre-formed heat re-flowable bonding members in which case the lower ends 14b of the pins 14 would be bonded with conductive joints formed by re-flow, but not necessarily joints made of solder. Similarly, the upper ends 14a of the pins could be connected to the upper circuit board 12 with conductive joints formed by re-flow, but not necessarily joints made of solder.

While we have described several embodiments of our discrete contact with attached heat re-flowable bonding member and circuit board assemblies made therewith, it will be understood by those skilled in art that our invention may be modified in both arrangement and detail. The use of the words “upper” and “lower” is merely for convenience in describing the structures illustrated. The boards and pins could be assembled and/or used in any orientation. Therefore, the protection afforded our invention should only be limited in accordance with the scope of the following claims.

We Claim:

1. A surface mount contact for attachment to a circuit board, comprising:
an elongate electrically conductive pin defining a shaft having a longitudinal axis and having an upper end and a lower end;
a pre-formed heat re-flowable bonding member attached to the lower end of the pin; and
an insulator surrounding the shaft of the pin intermediate the upper and lower ends and adjacent the pre-formed heat re-flowable bonding member.

2. The surface mount contact of claim 1 wherein the pin has a cylindrical cross-section.

3. The surface mount contact of claim 1 wherein the upper end of the pin is formed with a head with an outer surface that is dimensioned to be positioned on, and bonded to, a conductive pad on a circuit board, and the lower end of the pin is dimensioned and configured to be attached to a lower circuit board.

4. The surface mount contact of claim 3 wherein the head is formed with at least one channel that opens through an outer surface of the head and a peripheral wall of the head.

5. The surface mount contact of claim 1 wherein the pin is provided with a shoulder for establishing a predetermined vertical position along the longitudinal axis relative to a reference surface.

6. The surface mount contact of claim 1 wherein the insulator is a collar.

7. The surface mount contact of claim 1 wherein the pre-formed heat re-flowable bonding member is a solder ball.

8. The surface mount contact of claim 7 wherein the insulator has a conductive pad formed thereon.

9. The surface mount contact of claim 1 wherein the insulator is made of a high temperature plastic resin.

10. The surface mount contact of claim 6 wherein the collar is press fit around the pin.

11. A circuit board assembly comprising:
an upper circuit board;
a plurality of electrically conductive pins each having a shaft with upper and lower ends, the upper ends of the pins being attached to the upper circuit board and being arranged in a predetermined pattern;
a plurality of insulators each surrounding the shaft of a corresponding pin;
a lower circuit board opposing and generally parallel with the upper circuit board, the lower circuit board having a plurality of conductive pads arranged in the predetermined pattern; and
a plurality of conductive joints each formed by re-flow of a pre-formed heat re-flowable bonding member attached to the lower end of a corresponding pin, each conductive joint bonding the lower end of a corresponding pin and a corresponding conductive pad and forming an electromechanical bond therebetween.

12. The circuit board assembly of claim 11 wherein the conductive joints are solder joints.

13. The circuit board assembly of claim 12 wherein the upper ends of the pins are attached to the upper circuit board by a plurality of second solder joints.

14. The circuit board assembly of claim 11 wherein the upper ends of the pins are inserted into corresponding holes in the upper circuit board and each pin has a shoulder positioned between the insulator and the upper circuit board that establishes a predetermined longitudinal position of the pin relative to the upper circuit board.

15. The circuit board assembly of claim 12 wherein each insulator is formed with a second conductive pad that is bonded by a corresponding second solder joint to a corresponding second conductive pad on the upper circuit board.

16. The circuit board assembly of claim 15 wherein a first melting temperature of the solder in the plurality of second solder joints is above a second melting temperature of the solder in the solder joints that bond the lower ends of the pins to the conductive pads on the lower circuit board.

17. The circuit board assembly of claim 11 wherein the upper end of each pin is formed with a head with an outer surface that is dimensioned to be positioned on, and bonded to, a second conductive pad on the upper circuit board.

18. The circuit board assembly of claim 17 wherein the head is formed with at least one channel that opens through the outer surface of the head and a peripheral wall of the head.

19. The circuit board assembly of claim 11 wherein the pre-formed heat re-flowable bonding member is made of a material selected from the group consisting of Tin/Lead solder, Tin/Bismuth solder, conductive epoxy, brazing compound, welding compound and solder paste.

20. A circuit board assembly comprising:
a generally planar upper circuit board;
a plurality of electrically conductive pins each having a shaft with upper and lower ends, the upper ends of the pins being attached to plated through holes in the upper circuit board by a plurality of first solder joints and being arranged in a predetermined pattern;
a plurality of discrete insulators each surrounding the shaft of a corresponding pin;
a generally planar lower circuit board opposing and generally parallel with the upper circuit board, the lower circuit board having a plurality of conductive pads arranged in the predetermined pattern; and
a plurality of second solder joints formed by re-flowing a pre-formed heat re-flowable bonding member, each of the second solder joints bonding a lower end of a corresponding pin and a corresponding conductive pad, a first portion of the pins having lower ends that directly contact their corresponding conductive pads and a second portion of the pins having their lower ends spaced slightly above their corresponding conductive pads.

21. A surface mount contact for attachment to a circuit board, comprising:
an elongate electrically conductive pin defining a shaft having a longitudinal axis and having an upper end and a lower end;
a pre-formed heat re-flowable bonding member attached to the lower end of the pin; and
an insulator with a conductive pad formed on an upper surface thereof surrounding the shaft of the pin adjacent the pre-formed heat re-flowable bonding member.

22. The contact of claim 21 wherein the pre-formed heat re-flowable bonding member is a solder ball.

23. The contact of claim 21 wherein the upper end of the pin extends above the conductive pad formed on the upper surface of the insulator.

24. The contact of claim 21 wherein the upper end of the pin does not extend above the conductive pad formed on the upper surface of the insulator.

25. The contact of claim 21 wherein the insulator and conductive pad are formed of Copper clad FR-4 material.
